(19) United States
(12) Patent Application Publication
(10) Pub. No.: US 2015/0263116 A1
(43) Pub. Date: Sep. 17, 2015

(54) High electron mobility transistors with improved gates and reduced surface traps

(71) Applicants: Chunong Qiu, Brossard (CA); Jay-Hsing Wu, Brossard (CA); Cindy X. Qiu, Brossard (CA); Yi-Chi Shih, Los Angeles, CA (US); Ishiang Shih, Brossard (CA)

(72) Inventors: Chunong Qiu, Brossard (CA); Jay-Hsing Wu, Brossard (CA); Cindy X. Qiu, Brossard (CA); Yi-Chi Shih, Los Angeles, CA (US); Ishiang Shih, Brossard (CA)

(21) Appl. No.: 13/999,623

(22) Filed: Mar. 14, 2014

(51) Int. Cl. H01L 29/423; H01L 29/778

(52) U.S. Cl. CPC H01L 29/42372; H01L 29/778

(57) ABSTRACT

The present invention is related to high electron mobility transistors for power switching and microwave amplification and switching. More specifically, it related to a high electron mobility transistor with an improved gate to enhance the performance. When fabricating a high electron mobility thin film transistors, a first gate metal layer made of chromium alloy or tungsten alloy is deposited to reduce surface traps and to enhance the stability and integrity of the gates.

### FIELD OF INVENTION

Present invention is related to high electron mobility transistors for power switching and microwave amplification and switching. More specifically, it related to a high electron mobility transistor with an improved gate to reduce surface traps and to enhance the stability and the performance of the devices.

### BACKGROUND OF THE INVENTION

For electronic switching and amplification of electrical signals at low frequencies of about or below 1 GHz, silicon based devices in metal-oxide-semiconductor (MOS) structure or bipolar junction transistor (BJT) structure are often used. Silicon devices for such applications include MOS field effect transistors (MOSFET), insulated gate bipolar transistors (IGBT) and lightly doped drain MOS field effect transistors (LDMOSFET). For electrical signals at frequencies higher than 1 GHz, the silicon based devices may not be suitable for applications such as microwave and millimetre wave switching and amplification because of the relatively low charge carrier mobility and breakdown electric field of the doped silicon. Due to the relatively low charge carrier mobility of in the order of 1,000 cm²/V-sec, the devices or transistors can not be switched or operated at too high a frequency. Due to the relatively low breakdown electric field of about 0.3×10⁶ V/cm, the transistors can not be operated at large voltages and hence at high power because of small dimensions/thicknesses and easy material breakdown. In addition to switching of power, these devices may be used to perform high voltage AC to DC or DC to AC conversion. In these high power conversion applications, devices must be designed to sustain high voltages of up to several kilovolts. To obtain good switching and high amplification efficiency, the series resistance between two output terminals of a transistor must be low. Such requirements need semiconductors having high charge carrier mobilities as the series resistance decreases with the increase in mobility. Another important requirement for the transistors is stability and reliability over the entire life time of the devices which can be as long as 10⁶ or 10⁷ hours. Finally, the transistors should be able to be manufactured using industrial semiconductor technology and equipment.

It is clear from the above comments that for efficient power switching and amplification, semiconductors needs to have large carrier or electron mobility, large breakdown electrical field, good thermal stability and manufacturability by industrial semiconductor technologies.

Recently, a new class of semiconductors based on III-nitrides are being developed, where III represents group III elements including Al, Ga and In. Examples of the new class of semiconductors include AlN, GaN, InN and their alloys such as AlGaN, InGaN and AlInN. Some of these new III-nitrides have exceptional electronic properties: their energy relaxation times, τ, are substantially smaller than that of the crystalline silicon. In addition, energy bandgaps of the III-nitrides, specifically GaN, AlGaN and AlN, are large compared to Si and GaAs. Because of the small relaxation time and large energy bandgaps, devices fabricated using these III-nitrides semiconductors and their alloys have breakdown electric fields substantially greater than Si and GaAs, the two most important electronic semiconductors in industry. For instance, the breakdown electric field for GaN and AlGaN is 3.0×10⁶ V/cm which is about 10 times of that for Si and GaAs. Therefore, the III-nitrides can sustain larger voltages with the same device dimensions or thicknesses. It is also noted that mobilities of charge carriers of the III-nitrides are greater than silicon. And more importantly, the critical junction temperatures of stable operation for some of the III-nitrides are significantly higher than GaAs and Si. As a comparison, the critical junction temperature is 250° C. for silicon devices, 400° C. for GaAs devices and 600° C. for devices based on III-nitrides. Combining the high critical electric field for breakdown, high mobility and the high critical temperature for stable operation, it is evident that devices and circuits based on III-nitrides are ideal for high power switching and high frequency millimetre wave circuit applications. It is quite possible for the III-nitrides to replace some of the high frequency applications currently provided by GaAs or Si technology.

Present invention is related to a high electron mobility transistor (HEMT) based on III-nitrides for power switching and amplification. Therefore, a brief description on the structure and operation of a HEMT based on the III-nitrides is given. The III-nitrides are deposited on substrates of sapphire, silicon carbide or silicon. Take silicon substrate as an example, the deposition of the III-nitride films are made at elevated temperature and preferably on (111) plane or (100) plane. After the deposition and during cooling to near room temperature, there are tensile stresses induced in the deposited III-nitride epitaxial layers. For example in InGaN—AlGaN—GaN—Si with heavily doped InGaN, undoped AlGaN and undoped GaN layers, the tensile stress induced in the AlGaN layer leads to charge polarization in the AlGaN layer. The above InGaN—AlGaN—GaN thus forms composite epitaxial channel layers or composite channel layers. Due to the charge polarization and tensile stresses, positive polarization charges are induced in the AlGaN near the GaN layer whereas negative polarization charges are induced on or near the top surface of the AlGaN layer. The positive polarization charges induce negative mobile charges of equal amount on the top of the GaN layer forming a mobile charge sheet which forms a conduction channel for the transistor to be formed. The transistor to be formed will have a channel, a source, a drain and a gate with a gate voltage applied to it for channel charge modulation and the transistor device is called a high electron mobility transistor (HEMT). This is because the negative mobile charges are induced in the GaN, which is undoped, so that impurity scattering is a minimum. Hence, the mobility of the induced negative free charges in GaN is high. To enhance further the performance, impurity doping may be introduced into AlGaN layer to donate mobile or free electrons to the adjacent GaN layer. It is thus clear that in the III-nitride HEMTs, stresses induced in the III-nitride layers are required for the transistor to operate.

One of the issues of the III-nitride HEMTs is the stability and integrity of the gate for the controlling of channel charges especially for high power switching and amplification. There is often an unwanted effect due to a difference in expansion coefficients between the gate material, which is a metal, and the channel layers, which are composite III-nitride films, InGaN, AlGaN and GaN in this case. The thermal expansion coefficients of InGaN, AlGaN and GaN are greater than that of silicon. The metals used for the formation of the gate have even larger thermal expansion coefficients. Therefore, during device fabrication and subsequent operation, there are substantial strain and/or stresses in the composite channel layers of InGaN, AlGaN and GaN. These strain or stresses can lead to degradation of the gate hence the HEMT it attaches to.

When the HEMT is operated in ON state at a high power level, significant amount of unwanted heat will be dissipated into the channel region, leading to a temperature rise of the channel layers and adjacent transistor components including the drain contact, the source contact and more importantly the gate. The effect of dissipated heat on temperature rise in the gate is more severe as the gate is directly positioned in the channel region and it has small dimension or length which can be as small as 0.1 μm. When the HEMT is switched OFF, the unwanted dissipation of heat in the channel region decreases to zero and the temperature also decreases. During the life time of the HEMT, continuous ON/OFF operation can take place frequently. Therefore, considerable thermal stressing will take place in the channel region and hence in the gate metal. Due to the difference in thermal expansion coefficient between the semiconductor channel layers and the gate materials, significant strain or stresses can be induced in the gate and in the channel. Under more severe situation, even a partial microscopic deformation of the gate or a partial detachment of the gate from the channel layers may take place, leading to degradation of the gate. Such degradation may lead to incomplete or non-continuous contact between the gate and the channel layers which will reduce the modulation effect of the channel and the stability of the gate.

Furthermore, during the fabrication of the HEMT, some molecules of oxygen and water may attach to the surface of the semiconductor channel layer, and may diffuse or be absorbed into the surface region of the channel layer. These oxygen and water molecules may not be removed completely prior to the deposition of the gate metal layers and will get trapped between surface of the Schottky barrier layer in the channel region and the gate. If left alone, those trapped oxygen and water molecules will increase the interface states and result in a HEMT with unwanted non-constant drain current output characteristics. From the above comments, it is evident that there is a need to provide an improved gate for the HEMTs for switching of power or amplification.

### SUMMARY OF THE INVENTION

Present invention provides high mobility thin film transistors (HEMTs) with improved gates to enhance device performance. For those HEMTs, a first gate metal layer made of chromium alloy or tungsten alloy is deposited to minimize effects of oxygen and water trapped in the surface region of the Schottky barrier layer, to improve adhesion of the gate and increase stability and reliability of the thin film transistors.

### BRIEF DESCRIPTION OF THE SEVERAL VIEWS OF THE DRAWINGS

FIG. 1a is a simplified top view of a HEMT (100) with improved gate performance and FIG. 1b is a schematic cross-section of the gate (160) with a first gate layer (161) made of materials of NiₓCr₁₋ₓ and Ni_{y}W_{1-y} to improve adhesion and increase stability. FIG. 1c shows cross-sections of HEMT (100) and FIG. 1d shows the same HEMT with ledges (120LL, 120LR). FIG. 1e and FIG. 1f show cross-sections for situations with a provision of a gate insulator layer (160I, 160I′ respectively) between the gate (160) and the Schottky barrier layer (120S).

FIGS. 2a-2d show simplified cross sections of gates for a HEMT with improved gate performance, where the materials of the first gate layer are selected from a group of NiₓCr₁₋ₓ and Ni_{y}W_{1-y}. In FIG. 2a the gate head portion central axis is aligned with the gate stem portion central axis and FIG. 2b shows a gate where the head portion central axis is not aligned with the gate stem portion central axis in order to reduce unwanted capacitance between the gate and the source. FIG. 2c shows a situation when the Schottky layer is not etched whereas FIG. 2d is a situation when the Schottky layer is partially etched to form a Schottky barrier layer cavity (161SRC).

FIGS. 3a-3d′ show respectively cross-section of gate-channel region of a HEMT during different stages according to this invention, for the creation of a gate having a first gate layer containing Cr or W to enhance the adhesion and improve the stability. FIG. 3a is after the creation of gate stem portion cavity after the development of stem photoresist and FIG. 3b is after the creation of the gate head portion cavity. FIG. 3c is after an etching of Schottky barrier layer forming a Schottky barrier layer cavity, FIG. 3d is after the deposition of gate metal layers on the Schottky barrier layer without a Schottky barrier layer cavity while FIG. 3e is after the deposition of gate metal layers on Schottky barrier layer with a Schottky bather layer cavity. FIG. 3d′ shows an enlarged view of the gate (160) showing respective layers. FIG. 3f is after the deposition of passivation layer (350) without a Schottky barrier layer cavity whereas FIG. 3g is after the deposition of passivation layer (350′) with a Schottky barrier layer cavity.

FIG. 4 provides variation of drain to source current shown as “Drain Current” versus output drain voltage for a gate voltage at zero volts. Curve 1 for a HEMT with a pure Ni gate without Cr, and Curve 2 for a HEMT with a Ni gate containing 30% Cr. Both HEMTs are fabricated using same composite epitaxial layers on mono crystalline (111) silicon wafer.

### DETAIL DESCRIPTION OF THE PREFERRED EMBODIMENTS

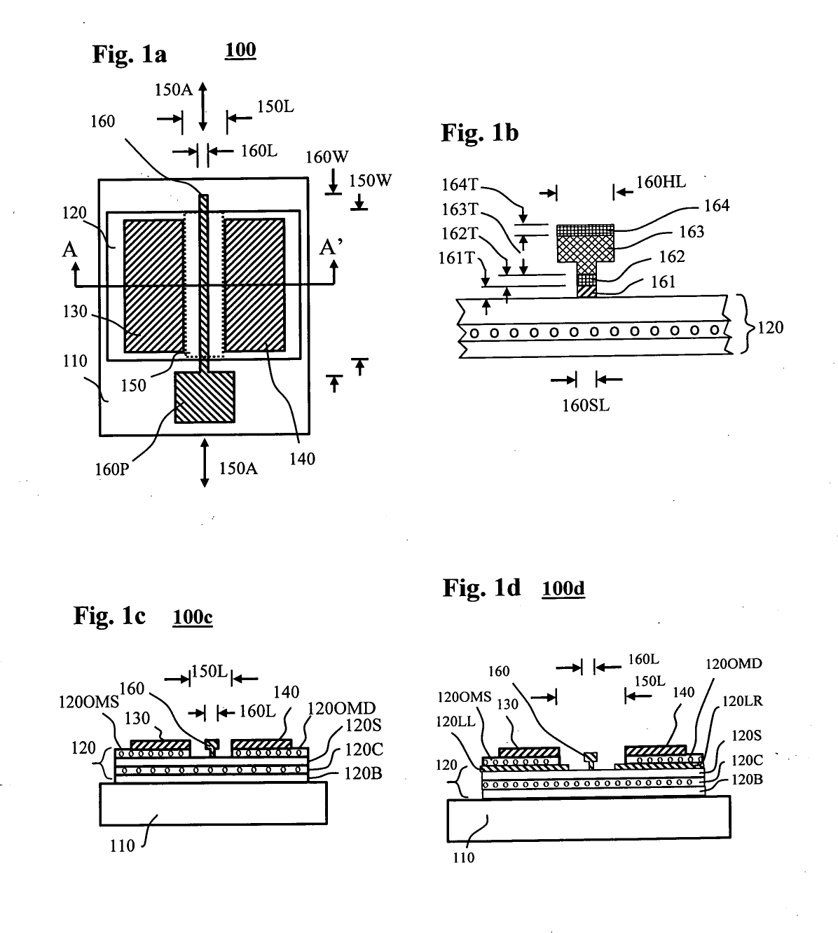

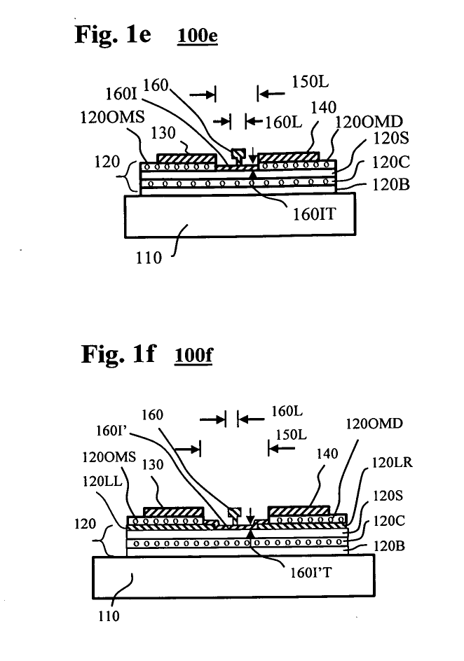

According to one embodiment of this invention, as shown in FIG. 1a, a high electron mobility transistor (HEMT, 100) with improved gate performance for power switching or for millimetre wave circuit applications comprises a substrate (110); a composite epitaxial channel layers (120); a source contact (130) and a drain contact (140) defining a channel region (150) having a channel region long axis (150A), a channel region width (150W) and a channel region length (150L); and a gate (160) having a gate length (160L), a gate width (160W) and a gate pad (160P). The gate (160) makes a rectifying or Schottky contact to the channel region (150). Resistance between the drain (140) and the source (130) is regulated by a voltage applied between the gate (160) and the source (130).

The gate (160) comprises a plurality of layers with a first gate layer (161, see FIG. 1b) having a first gate layer thickness (161T), a second gate layer (162) with a second gate layer thickness (162T) for adhesion and a third gate layer (163) with a third gate layer thickness (163T) to reduce resistance of said gate along the direction of said gate width (or channel long axis 150A). Materials of the first gate layer (161) is selected from material groups of NiₓCr₁₋ₓ and Ni_{y}W_{1-y} with values of x less than 0.4 and y values less than 0.3. The first gate layer (161) is selected and deposited in such a manner that the work function of the first gate layer are high and it has an improved adhesion on the channel region (150) to enhance stability and reliability during operation of modules or MMICs incorporating said HEMT. Materials for the second gate layer (162) may be selected from a group of Ti and TiW to achieve a good adhesion between the first gate layer (161) and the third gate layer (163). Materials for the third gate layer (163) may be selected from a group including Au, Cu and their mixtures. When Cu is selected as the third gate layer (163), a fourth gate layer (164) with a fourth gate layer thickness (164T) may be preferably adopted in order to minimize unwanted oxidation of the third gate layer. Gold is generally chosen for the fourth gate layer (164). Upon completion, a T-gate having a head length (160HL) and stem length (160SL) with improved performance is formed on the composite epitaxial channel layers (120).

Cross sectional views (100c, 100d) of the HEMT are provided in FIGS. 1c and 1d for clarification. As illustrated, there is a substrate (110), a composite epitaxial channel layer (120) consisting of a buffer layer (120B), a conductive channel layer (120C), a Schottky barrier layer (120S), a source ohmic layer (120OMS), a drain ohmic layer (120OMD), a source contact (130), a drain contact (140) and a gate (160). Ledge layers (120LL, 120LR, as shown in FIG. 1d) may be optionally adopted to reduce surface states on the Schottky barrier layer (120S). Under normal conditions, charge carriers will flow from the source contact (130) into the conductive channel (120C) in the source side, through the conductive channel and reach the conductive channel in the drain side and eventually into the drain contact (140) of the HEMT. Materials for the buffer layer (120B) may be AlN—AlGaN multiple layers, materials for the conductive channel layer (120C) may be undoped GaN or InGaN and materials for the Schottky barrier layer (120S) may be undoped or doped AlGaN. Materials of the source ohmic layer (120OMS) and drain ohmic layer (120OMD) may be heavily doped InGaN or GaN.

According to another embodiment of this invention, as illustrated in FIGS. 1e and 1f, a gate insulator layer (160I, 160I′ respectively in 100e and 100f) with a gate insulator thickness (160IT, 160I′T) is provided between the gate (160) and the Schottky barrier layer (120S) to reduce any unwanted leakage current between the gate and the source, and between the gate and the drain. Gate insulator layer (160I) and (160I′) also provide a partial passivation to the Schottky barrier layer (120S). Materials for the gate insulator layer are selected from a materials group including: silicon nitride, silicon oxide, silicon oxide nitride, magnesium oxide, hafnium oxide, aluminum oxide and their mixtures. The gate insulator thickness (160IT, 16I′T) is between 5 nm and 200 nm.

It should be noted that for high power and high voltage applications, more than one gate lines may be adopted. These gate lines are connected together and are electrically in parallel for each HEMT. In order to simplify the description and explanation, only one single gate line has been shown in the present descriptions and illustrations. It is thus understood that the present invention will be valid for HEMT devices having more than one gate line.

Material of the substrate (110) may be silicon, silicon carbide and sapphire as long as their crystalline quality is suitable for epitaxial of the III-nitride layers. The materials for the III-nitride layers may include AlN, GaN, InN, AlGaN, InGaN, AlInN and their alloys. Materials for drain contact (140) and source contact (130) can be selected from a combination of metals such as Ti, Ta, W, Pt, Al, Au and Cu as long as the first metal contacting the composite epitaxial layers can make a low contact resistance.

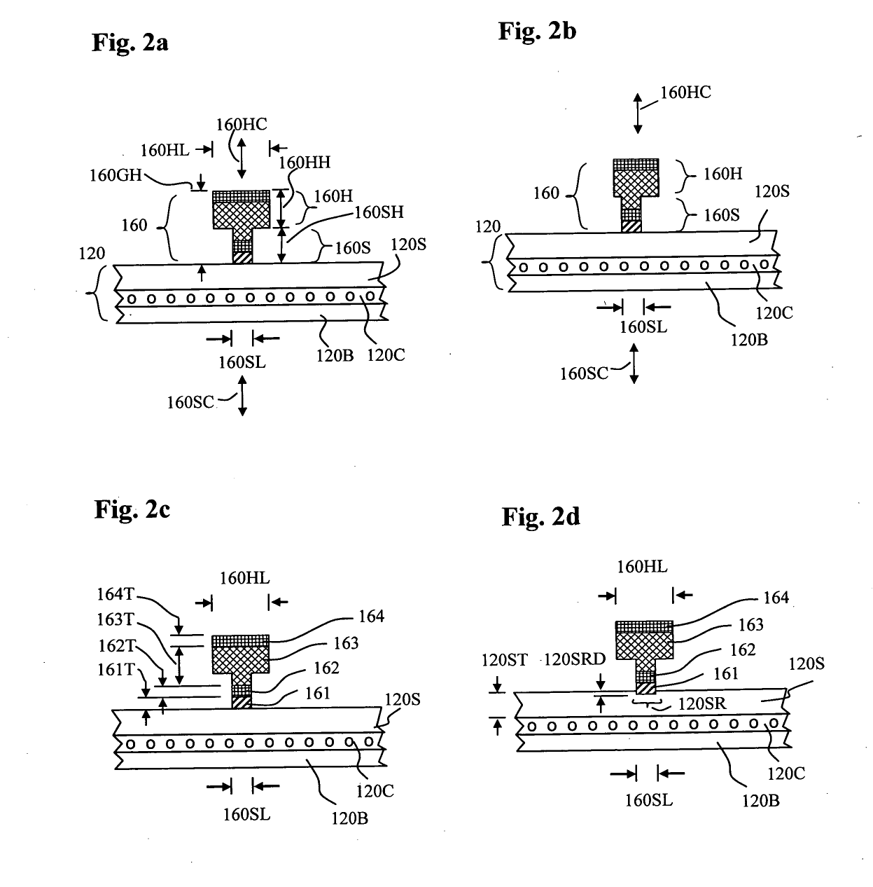

During the fabrication of the HEMT, some molecules of oxygen and water may attach themselves on the surface of the epitaxial III-nitride layers, and be absorbed in the surface of the Schottky barrier layer (120S). These oxygen and water molecules may not be removed completely prior to the deposition of the gate metal layers and may get trapped in the surface of the Schottky barrier layer (120S) in the channel region beneath the gate and induce unwanted interface states between the Schottky barrier layer and the gate. Therefore according to this invention, a multilayer gate is provided. In FIG. 2a, an enlarged view of the multilayer gate (160) on the composite epitaxial channel layer (120) is illustrated. The multilayer gate (160) has a gate height (160GH), a gate head portion (160H) with gate head portion height (160HH), a gate head portion length (160HL), a gate stem portion (160S) with a gate stem portion height (160SH), a gate stem portion length (160SL) which defines the performance of said HEMT, specifically the maximum switching speed of said HEMT. Furthermore, the gain of the amplifiers incorporating the HEMT improves as said gate stem portion length (160SL) of the HEMT is decreased. Said gate head portion (160H) has a gate head portion central axis (160HC), said gate stem portion (160S) has a gate stem portion central axis (160SC) which coincides with said gate head portion central axis (160HC) forming a T-gate. To enhance further the HEMT performance, as illustrated in FIG. 2b, gate head portion central axis (160HC) may be fabricated to be substantially away from gate stem portion central axis (160SC) forming a Γ-gate. In such a manner, the unwanted capacitance between the gate and the source will be reduced.

According to this invention and as illustrated in FIG. 2c, the multilayer gate (160) has a head portion and a stem portion and it consists of a first gate metal layer (161) with a first gate metal layer thickness (161T), which comprises metal alloys of NiₓCr₁₋ₓ or Ni_{y}W_{1-y} with values of x less than 0.4 and y values less than 0.3 to enhance the adhesion to the Schottky barrier layer (120S) and to minimize unwanted effects of oxygen or water molecules absorbed or diffused in the surface region of the Schottky barrier layer (120S); a second gate metal layer (162) with a second gate metal layer thickness (162T); a third gate metal layer (163) with a third gate metal layer thickness (163T). Materials of said second metal layer (162) are selected from Ti and TiW to ensure adhesion of the third gate metal layer (163). The third gate metal layer (163) is selected from a material group of Cu and Au. When Cu is selected for the third gate metal layer (163), a fourth gate metal layer (164) with a fourth gate metal layer thickness (164T) made of Au is adopted in order to reduce unwanted oxidation of said Cu third gate metal layer and facilitate subsequent wire bonding. Therefore, according to this invention, with the adoption of metals containing Cr or W in the first gate metal layer (161), unwanted effect of oxygen and water trapped in surface region of said Schottky barrier layer (120S) can be minimized and avoided. To enhance further the stability of the HEMT, as shown in FIG. 2d, a barrier recess region (120SR) is made in the Schottky barrier layer (120S) of a thickness (120ST) to a barrier recess region depth (120SRD) so that a portion of said first gate metal layer (161) is deposited in and locked in said recess region (120SR).

In order to improve the thermal stability of the present HEMT, it is preferable to deposit a layer of passivation material such as silicon nitride and silicon oxide nitride, silicon oxide nitride, magnesium oxide, hafnium oxide, aluminum oxide and their mixtures over the HEMT and the switching circuit or millimetre wave circuit containing said HEMT. As the deposition technology of a passivation layer is understandable to a person skilled in the art, more description will not be given here.

As stated before, the substrate may be made using materials such as silicon, silicon carbide and sapphire as long as their crystalline quality is suitable for epitaxial growth of the III-nitride layers. The materials for the III-nitride composite channel layers may include AlN, GaN, InN, AlGaN, InGaN, AlInN and their alloys.

During the fabrication of the HEMT, some molecules of oxygen and water may attach on the surface of the epitaxial III-nitride layers, and be absorbed in the surface of Schottky barrier layer in the channel region. These oxygen and water molecules may not be removed completely prior to the deposition of the gate metal layers and get trapped in the surface of the Schottky barrier beneath the gate and cause unwanted interface states between the Schottky barrier layer and the gate. According to this invention, the effects of the oxygen and water molecules are reduced or passivated by adopting a first gate layer selected from alloys of NiₓCr₁₋ₓ and Ni_{y}W_{1-y} with values of x less than 0.4 and y values less than 0.3.

It should be noted that for high power for high voltage applications, more than one gate lines may be adopted. These gate lines are connected together and electrically in parallel for each HEMT. However, in order to simplify the description and explanation, only one single gate line has been shown in the present description and figures. It is thus understood that the present invention will be valid for HEMT devices having more than one gate line.

Materials for drain contact and source contact can be selected from a group of metals such as Ti, W, Pt, Al, Au and Cu as long as the first metal contacting the composite epitaxial layers can make a low contact resistance.

In order to improve further the stability of HEMT and switching circuits and millimetre wave circuits containing said HEMT in subsequent operation for power switching and millimetre wave amplification, a passivation layer is deposited onto surfaces of said HEMT and other parts of said switching circuits and millimetre waver circuits to reduce surface traps and to enhance reliability and stability of said high electron mobility transistor, material of said passivation layer is selected from a material group of silicon nitride, silicon oxide, silicon oxide nitride, magnesium oxide, hafnium oxide, aluminum oxide and the mixtures.

The HEMT device according to this invention with improved gate performance may well be incorporated in a millimetre wave integrated circuits for the amplification and processing of microwave signals and be incorporated into power modules circuits for switching and regulation of high electrical power.

According to yet another embodiment of this invention, a gate insulator layer with a gate insulator thickness is further provided between the gate (160) and the Schottky barrier layer (120S) in FIGS. 2a˜2d, to reduce unwanted leakage current between said gate and said source, and between said gate and said drain, and to provide a partial passivation to said Schottky barrier layer (120S). Materials for said gate insulator layer are selected from a materials group of silicon nitride, silicon oxide, silicon oxide nitride, magnesium oxide, hafnium oxide, aluminum oxide and their mixtures. Said gate insulator thickness is selected between 5 nm and 200 nm, to reduce unwanted leakage current between said gate and said source, and between said gate and said drain, and to provide a partial passivation to said Schottky barrier layer.

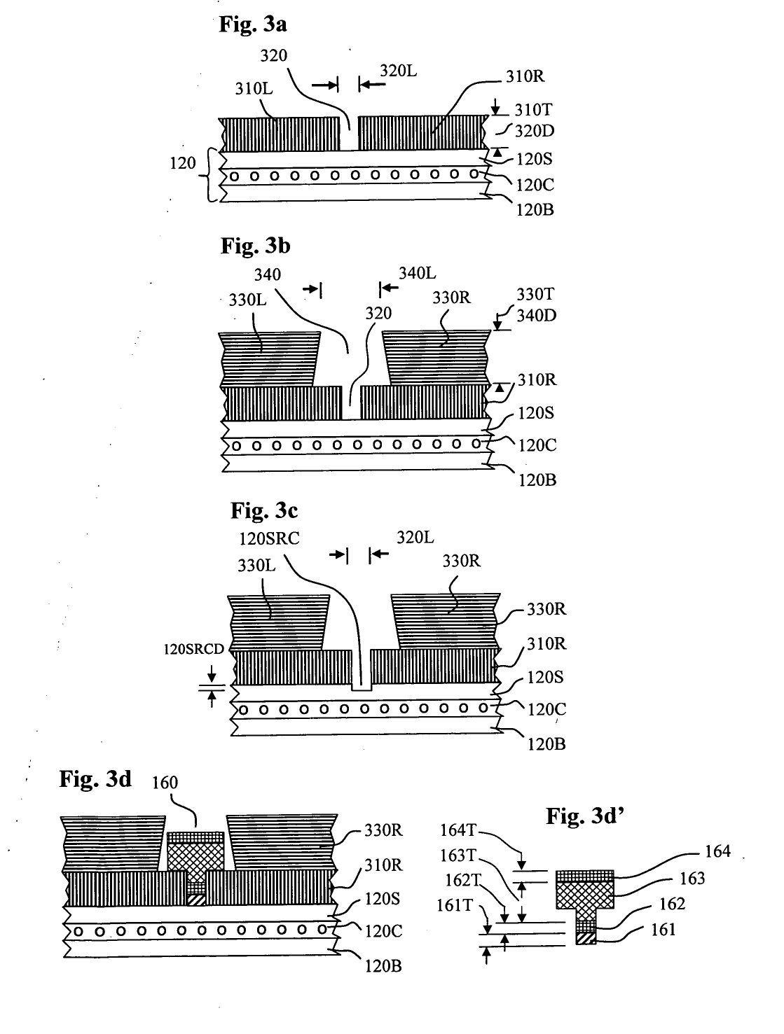

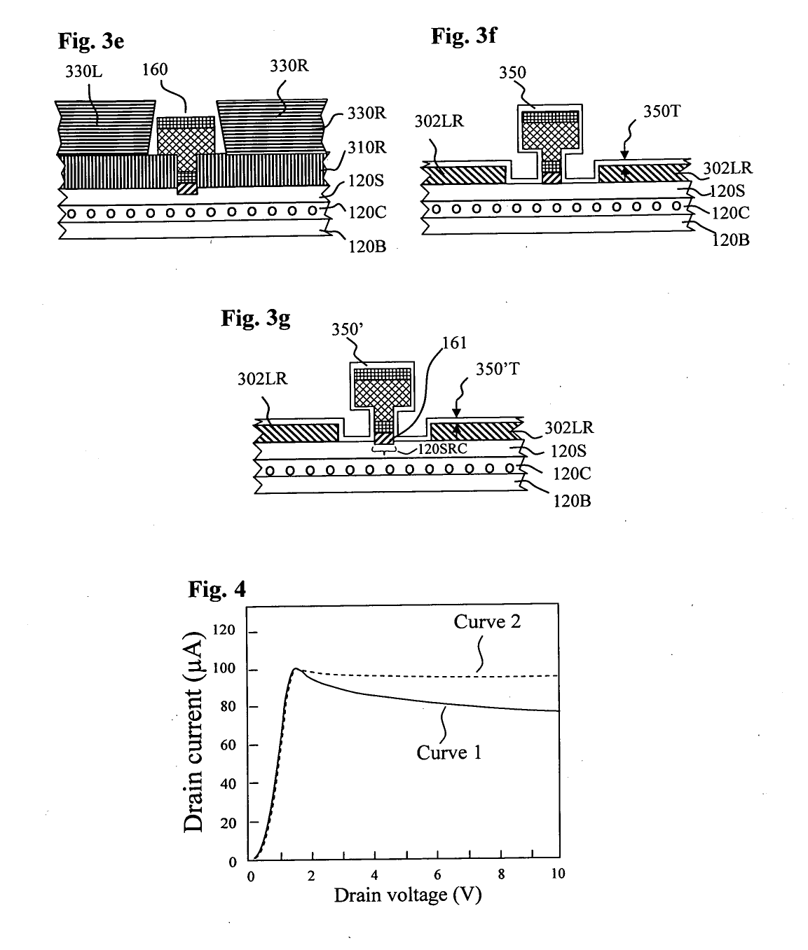

The HEMT devices with improved stability and reliability according to this invention may be fabricated using industrial equipment. To simplify the description, the patterning and etching of source ohmic layer (120OMS), drain ohmic layer (120OMD) and ledge layers (120LL, 120LR) and the patterning and deposition of source contact (130) and drain contact (140) shown in FIGS. 1a, 1c and 1d will not be given here. As shown in FIG. 3a, the composite epitaxial channel layer (120) comprises a buffer layer (120B), a conductive channel layer (120C) and a Schottky barrier layer (120S). On the composite epitaxial layer (120), form a stem photoresist (310R, 310L) to a stem portion photoresist thickness (310T) with a stem cavity (320) between (310R) and (310L) to reveal a portion of the Schottky barrier layer (120S). The stem cavity (320) has a stem cavity length (320L) and a stem cavity depth (320D) which is the same as the stem portion photoresist thickness (310T). The stem cavity length (320L) is controlled to be 150 nm or less to define a gate stem portion in subsequent steps. As shown in FIG. 3b, form a head photoresist (330R, 330L) to a head portion photoresist thickness (330T) with a head cavity (340) between (330R) and (330L) to reveal the stem portion cavity (320) and a portion of the Schottky barrier layer (120S). The head cavity (340) has a head cavity length (340L) and a head cavity depth (340D) which is the same as the head portion photoresist thickness (330T). The head portion cavity length (340L) is controlled to be 500 nm to 1,000 nm to define a gate head portion in subsequent steps. To enhance further the stability and reliability of gate stem portion to be deposited in subsequent steps, as shown in FIG. 3c, generate a barrier recess cavity (120SRC) with a barrier recess cavity depth (120SRCD) by etching. A thorough cleaning is performed to clean the exposed portion of the Schottky barrier layer (120S) or the barrier recess cavity (120SRC). This is followed by vacuum deposition of a first gate layer (161, FIGS. 3d and 3d′) with a first gate layer thickness (161T, see FIG. 3d′), materials of which are selected from a group including NiₓCr₁₋ₓ and Ni_{y}W_{1-y} with values of x less than 0.4 and y values less than 0.3. A second gate layer (162) with a second gate layer thickness (162T) for adhesion and a third gate layer (163) with a third gate layer thickness (163T) to reduce resistance of the gate are then deposited. The first gate layer (161) is selected and deposited to ensure that the work function of the first gate layer is high and it has improved adhesion on the Schottky barrier layer in the channel region to enhance stability and reliability during operation of modules or MMICs incorporating said HEMT. Materials for the second gate layer may be selected from a metal group of Ti and TiW to achieve good adhesion between the first gate layer (161) and the third gate layer (163). Materials of the third gate layer may be selected from a group of Ti, W, Pt, Al, Au and Cu or their mixtures. When Cu is selected as the third gate layer (163), a fourth gate layer (164) with a fourth gate layer made of Au with a thickness (164T) is preferably deposited. The fourth gate layer is deposited to minimize unwanted oxidation of the Cu third gate layer and to facilitate subsequent wire bonding.

After the deposition of the gate metal layers, the unwanted metal layers outside the gate region, the remaining stem portion photoresist and head portion photoresist are removed by a lift-off process. After cleaning and drying, a passivation layer (350) is deposited to a passivation layer thickness (350T) on the entire structure to enhance the thermal stability. The HEMT device in FIG. 3f is now ready for subsequent wire bonding and testing.

In the case where a barrier recess cavity (120SRC) is created, the situation of deposition is shown in FIG. 3g so that a portion or the entire first gate layer (161) is deposited in said barrier recess cavity (120SRC) to enhance the stability and reliability. After the deposition of the gate metal layers, unwanted metal layers outside the gate region, the remaining stem portion photoresist and head portion photoresist are removed by a lift-off process. After cleaning and drying, a passivation layer (350′) is deposited to a passivation layer thickness (350′T) on the entire structure to enhance the thermal stability. The HEMT device in FIG. 3g is now ready for subsequent wire bonding and testing. Material of said passivation layers (350 and 350′) are selected from a material group of silicon nitride, silicon oxide, silicon oxide nitride, magnesium oxide, hafnium oxide, aluminum oxide and the mixtures.

According to an embodiment of this invention, a gate insulator layer with a gate insulator thickness can be further provided between said gate (160) and Schottky barrier layer (120S), to reduce the unwanted leakage current between said gate and said source, and between said gate and said drain, and to provide a partial passivation to said Schottky barrier layer (120S). Materials for said gate insulator layer are selected from a materials group: silicon nitride, silicon oxide, silicon oxide nitride, magnesium oxide, hafnium oxide, aluminum oxide and their mixtures. Said gate insulator thickness is selected between 5 nm and 200 nm.

Output characteristics of a HEMT fabricated on a composite epitaxial channel layer deposited on a monocrystalline high resistivity (111) oriented Si wafer, with pure Ni Schottky gate is shown in Curve 1 in FIG. 4 where drain to source current is shown as “Drain Current” and plotted versus output drain voltage for a gate voltage at zero volt. It is seen that the drain to source current increases rapidly with the increase in drain voltage from 0 volt, the drain current reaches a maximum at a drain voltage of about 1.5 volt then it decreases when the drain voltage is increased further from 1.5 volt to 10 volts (Curve 1). The decrease in the drain current with the increase in the drain voltage deviates from the ideal constant drain current output characteristics of a HEMT with a finite output resistance of a large magnitude. This unwanted decrease in the drain current (Curve 1) is due to the interface states in the channel Schottky barrier layer beneath the first gate layer which in this case is pure Ni. For efficient switching and amplification, it is preferable to have essentially constant drain current as the drain voltage is increased so that the equivalent output resistance is infinite. Curve 2 is output characteristics of a HEMT also fabricated on a composite epitaxial channel layer deposited on a monocrystalline high resistivity (111) oriented Si wafer, but with NiCr as the first gate metal layer. It is clearly seen that output drain current is essentially constant between 1.5 volts and 10 volts of drain voltage. The output performance of the HEMT has thus improved by the adoption of NiCr as the first gate layer.

1. A high electron mobility transistor for power switching and millimetre wave amplification with an improved gate and reduced surface traps, comprising
a substrate;
a composite epitaxial channel layers, comprising a buffer layer, a conducting layer and a Schottky barrier layer;
a source ohmic layer and a drain ohmic layer;
a drain contact and a source contact defining a channel region with a channel length and a channel width;
a multilayer gate with a gate length and a gate width, said multilayer gate having at least a first gate layer with a first gate layer thickness, a second gate layer with a second gate layer thickness and a third gate layer with a third gate layer thickness, wherein said first gate layer is deposited on said Schottky barrier layer and is made of metal alloys containing tungsten to minimize surface traps in said channel region beneath said gate, to improve adhesion and to stabilize current flowing from said drain to said source.

2. A high electron mobility transistor for power switching and millimetre wave amplification with an improved gate and reduced surface traps as defined in claim 1, wherein said metal alloys of said first gate layer is NiCrW.

3. A high electron mobility transistor for power switching and millimetre wave amplification with an improved gate and reduced surface traps as defined in claim 1, wherein said metal alloys of said first gate layer is Ni_{y}W_{1-y}, wherein y is less than 0.4.

4. A high electron mobility transistor for power switching and millimetre wave amplification with an improved gate and reduced surface traps as defined in claim 1, whereas materials for said second gate layer is selected from Ti and TiW to improve adhesion between said first gate layer and said third gate layer.

5. A high electron mobility transistor for power switching and millimetre wave amplification with an improved gate and reduced surface traps as defined in claim 1, whereas materials for said third gate layer is selected from Au and alloy of Au and Cu to reduce resistance of said multilayer gate.

6. A high electron mobility transistor for power switching and millimetre wave amplification with an improved gate and reduced surface traps as defined in claim 1, material for said third gate layer is Cu and said multilayer gate further comprises a fourth gate layer made of Au deposited on top of said third gate layer to facilitate wire bonding and prevent surface oxidation.

7. A high electron mobility transistor for power switching and millimetre wave amplification with an improved gate and reduced surface traps as defined in claim 1, wherein said drain contact and source contact are composite metal layers, materials of which are selected from a group of Ti, W, Pt, Al, Au and Cu so that contacting metal makes a low resistance ohmic contact to said source ohmic layer and said drain ohmic layer.

8. A high electron mobility transistor for power switching and millimetre wave amplification with an improved gate and reduced surface traps as defined in claim 1, wherein said composite epitaxial channel layers are selected from a combination of material group of AlN, GaN, InN, AlGaN, InGaN, AlInN and their alloys.

9. A high electron mobility transistor for power switching and millimetre wave amplification with an improved gate and reduced surface traps as defined in claim 1, wherein materials of said source ohmic layer and drain ohmic layer are heavily doped InGaN or GaN.

10. A high electron mobility transistor for power switching and millimetre wave amplification with an improved gate and reduced surface traps as defined in claim 1, further comprising a source ledge layer and a drain ledge layer being deposited on said composite epitaxial channel layer and under said drain and said source to reduce leakage current and increase breakdown voltage, material of said ledge layers being selected from a group of metal oxide, metal oxide nitride and metal nitride, wherein said metal is selected from a group of In, Zn, Sn, Ga and their alloys.

11. A high electron mobility transistor for power switching and millimetre wave amplification with an improved gate and reduced surface traps as defined in claim 1, wherein said multilayer gate comprises a head portion having a head portion central axis and a stem portion having a stem portion axis, said head portion central axis is aligned with said stem portion central axis, forming a multilayer T-gate structure.

12. A high electron mobility transistor for power switching and millimetre wave amplification with an improved gate and reduced surface traps as defined in claim 1, wherein said multilayer gate comprises a head portion having a head portion central axis and a stem portion having a stem portion axis, said head portion central axis is not aligned with said stem portion central axis, forming a multilayer Γ-gate structure.

13. A high electron mobility transistor for power switching and millimetre wave amplification with an improved gate and reduced surface traps as defined in claim 1, further comprising a Schottky barrier cavity with a Schottky barrier cavity depth in a surface region of said Schottky bather layer to accommodate a part or a whole of said first gate layer, to enhance reliability and stability of said high electron mobility transistor.

14. A high electron mobility transistor for power switching and millimetre wave amplification with an improved gate and reduced surface traps as defined in claim 1, further comprising a passivation layer to enhance reliability and stability of said high electron mobility transistor, material of said passivation layer is selected from a material group of silicon nitride, silicon oxide, silicon oxide nitride, magnesium oxide, hafnium oxide, aluminum oxide and the mixtures.

15. A high electron mobility transistor for power switching and millimetre wave amplification with an improved gate and reduced surface traps as defined in claim 1, further comprising a gate insulator layer deposited between said Schottky barrier layer and said multilayer gate, to provide partial passivation to said Schottky barrier layer channel region and to reduce leakage current between said multilayer gate and said source, reduce leakage current between said multilayer gate and said drain, to enhance reliability and stability of said high electron mobility transistor, material of said gate insulator layer is selected from a material group of silicon nitride, silicon oxide, silicon oxide nitride, magnesium oxide, hafnium oxide, aluminum oxide and the mixtures.

16. A high electron mobility transistor for power switching and millimetre wave amplification with an improved gate and reduced surface traps as defined in claim 1, wherein said multilayer gate comprises a head portion and a stem portion, length of said stem portion is preferably selected to be less than 1 μm and more preferably selected to be less than 250 nm, height of said stem portion is greater than 100 nm to reduce capacitance between said multilayer gate and source and to reduce capacitance between said multilayer gate and drain to enhance switching performance of switching circuits and MMICs containing said high electron mobility transistor.

17. A high electron mobility transistor for power switching and millimetre wave amplification with an improved gate and reduced surface traps as defined in claim 1, wherein said substrate is selected from a material group of silicon, silicon carbide and sapphire.
